(19) United States
(12) Patent Application Publication
(10) Pub. No.: US 2007/0200234 A1
(43) Pub. Date: Aug. 30, 2007

(54) Flip-Chip Device Having Underfill in Controlled Gap

(75) Inventors: Mark A. Gerber, Lucas, TX (US); Sohichi Kadoguchi, Oita (JP); Masakazu Hakuno, Oita-Pref (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/424,555

(22) Filed: Jun. 16, 2006

Related U.S. Application Data
(60) Provisional application No. 60/777,699, filed on Feb. 28, 2006.

(51) Int. Cl. H01L 23/48

(52) U.S. Cl. 257/734

(57) ABSTRACT

A flip-chip and underfilled device, which includes a semiconductor chip (101) with contact pads and a workpiece (102) with contact pads in matching locations; the workpiece may be an insulating substrate or another semiconductor chip. The workpiece and the chip are spaced by a gap (103) of substantially uniform average width. Attached to each chip contact pad is a column-shaped spacer (140), which includes two or more deformed spheres of non-reflow metals, preferably gold, bonded together to a height about equal to the gap width. The spacer is attached to the contact pad (110) substantially normal to the chip surface and extends from the chip pad to the matching workpiece pad (120); it is bonded to the workpiece pad by reflow metals (141) such as tin or tin alloy, which covers at least portions of the workpiece pad and the spacer. The gap may be filled with a polymer material (105) surrounding the reflow metal and spacers.

### FIELD OF THE INVENTION

The present invention is related in general to the field of semiconductor devices and processes, and more specifically to low profile flip-chip assembled devices, which provide a controllable gap between chip and substrate for uniform underfilling.

### DESCRIPTION OF THE RELATED ART

When an integrated circuit (IC) chip is assembled on an insulating substrate with conducting lines, such as a printed circuit motherboard, by solder bump connections, the chip is spaced apart from the substrate by a gap; the solder bump interconnections extend across the gap. The IC chip is typically a semiconductor such as silicon, silicon germanium, or gallium arsenide, the substrate is usually made of ceramic or polymer-based materials such as FR-4. Consequently, there is a significant difference between the coefficients of thermal expansion (CTE) of the chip and the substrate; for instance, with silicon (about 2.5 ppm/° C.) as the semiconductor material and plastic FR-4 (about 25 ppm/° C.) as substrate material, the difference in CTE is about an order of magnitude. As a consequence of this CTE difference, thermomechanical stresses are created on the solder interconnections, especially in the regions of the joints, when the assembly is subjected to temperature cycling during device usage or reliability testing. These stresses tend to fatigue the joints and the bumps, resulting in cracks and eventual failure of the assembly.

In order to distribute the mechanical stress and to strengthen the solder joints without affecting the electrical connection, the gap between the semiconductor chip and the substrate is customarily filled with a polymeric material, which encapsulates the bumps and fills any space in the gap. For example, in the well-known “C-4” process developed by the International Business Machines Corporation, polymeric material is used to fill any space in the gap between the silicon chip and the ceramic substrate.

The encapsulant is typically applied after the solder bumps have undergone the reflow process and formed the metallic joints for electrical contact between the IC chip and the substrate. A viscous polymeric precursor, sometimes referred to as the “underfill”, is dispensed onto the substrate adjacent to the chip and is pulled into the gap by capillary forces. The precursor is then heated, polymerized and “cured” to form the encapsulant.

It is well known in the industry that the temperature cycling needed for the underfill curing process can create thermomechanical stress on its own, which may be detrimental to the chip and/or the solder interconnections. Additional stress is created when the assembly is cooled from the reflow temperature to ambient temperature. The stress created by these process steps may delaminate the solder joint, crack the passivation of the chip, or propagate fractures into the circuit structures.

In general, the sensitivity to cracking of the solder joints and of the layered structures of integrated circuits is increasing strongly with decreasing size of the solder balls, as required by the ongoing miniaturization trend of semiconductor products, and with decreasing width of the gap as a consequence of the decreasing solder ball size. Furthermore, the decreasing width of the gap renders the polymer flow based on capillary force more and more unreliable, which in turn causes voids in the underfill material coupled with significant increase in size and non-uniformity of stress.

### SUMMARY OF THE INVENTION

Applicant recognizes the need for an assembly methodology, which, on one hand, can accept the shrinking ball diameter and ball pitch of flip-chip devices, yet on the other hand decouples the width of the gap in assembled devices from the ball diameter so that the polymer material can fill the gap uniformly without leaving voids. The stress-distributing benefits of the underfill material can thus be enjoyed without the deleterious side-effects of the underfilling process, resulting in enhanced device reliability. The methodology should be coherent, low-cost, and flexible enough to be applied to different semiconductor product families and a wide spectrum of design and process variations.

One embodiment of the invention is a flip-chip and underfilled device, which includes a semiconductor chip with contact pads and a workpiece with contact pads in matching locations; the workpiece may be an insulating substrate or another semiconductor chip. The workpiece and the chip are spaced by a gap of substantially uniform average width. Attached to each chip contact pad is a column-shaped spacer, which includes two or more deformed spheres of non-reflow metals, preferably gold, bonded together to a height about equal to the gap width. The spacer is attached to the contact pad substantially normal to the chip surface and extends from the chip pad to the matching workpiece pad; it is bonded to the workpiece pad by reflow metals such as tin or tin alloy, which covers at least portions of the workpiece pad and the spacer. The gap may be filled with a polymer material surrounding the reflow metal and spacers.

Another embodiment of the invention is a method for fabricating a flip-chip and underfilled semiconductor device. The method starts by providing a semiconductor wafer having devices with contact pads at pad locations. A ball, preferably gold or copper, is placed and squeezed on a first contact pad using the free air ball technique of wire bonding. A polymer precursor of known fluid mechanics properties is selected as underfill material. Thereafter, the ball-placing is repeated to form a column-shaped spacer with a height compatible with the fluid mechanics of the selected underfill material.

Next, a workpiece wafer is provided having contact pads in locations matching the locations of the device contact pads. Reflow metal such as tin or a tin alloy is applied to the contact pads either of the device wafer or the workpiece wafer. The workpiece wafer is then placed on the device wafer and the workpiece pads are aligned to the matching spacers on the device. Thermal energy is applied to reflow the metal on the contact pads for bonding the spacers to the workpiece so that the semiconductor wafer and the workpiece wafer are electrically connected, yet spaced by a gap according to the height of the spacers. Thereafter, the gap may be filled with the selected underfill material. Finally, and the assembled wafers are singulated, preferably by sawing, into discrete flip-chip and underfilled semiconductor devices.

Before this step of singulation, it is advantageous for some embodiments to encapsulate the assembled and underfilled semiconductor and workpiece wafers in a protective material.

The workpiece may be an insulating substrate integral with conductive lines, or it may be another semiconductor wafer.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1A depicts a schematic cross section of a semiconductor device assembled on a substrate with spacers, which determine the width of the gap between the assembled units necessary for uniform filling of the gap with a polymeric material.

FIG. 1B depicts a schematic cross section of a semiconductor device assembled on another substrate with a spacer, which determines the width of the gap between the assembled units necessary for filling of the gap with a polymeric material.

FIGS. 2 to 5 illustrate schematically the significant steps of the fabrication process of the spacer and the device assembly.

FIG. 2 shows schematically the squeezed sphere of a free air ball attached to a device contact pad.

FIG. 3 shows schematically the formation of a column-shaped spacer fabricated by two squeezed free air balls on a device contact pad.

FIG. 4 shows schematically the column-shaped spacer on the contact pad of a flipped device aligned with a substrate contact pad.

FIG. 5 shows schematically the device spacer in contact with the substrate bond pad, connected by reflow metal before the underfilling process step.

### DETAILED DESCRIPTION OF THE PREFERRED EMBODIMENTS

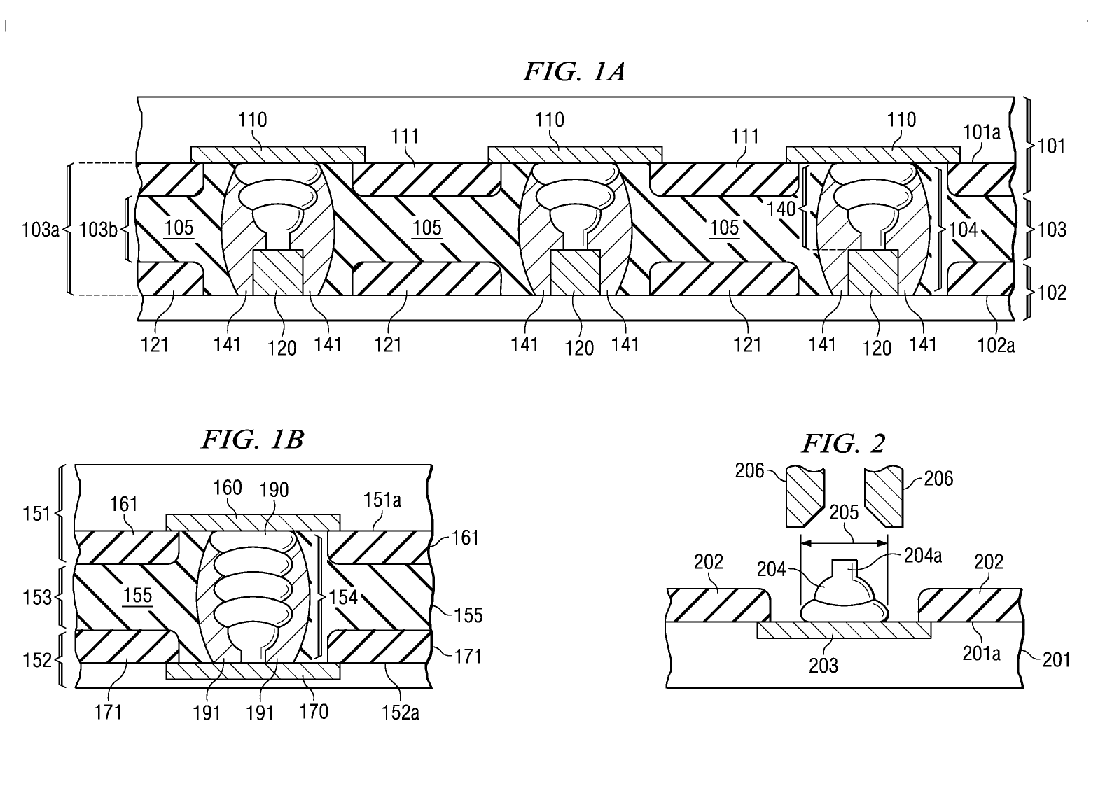

FIGS. 1A and 1B illustrate portions of assembled semiconductor devices. The device in FIG. 1A includes a semiconductor chip 101 spaced from a workpiece 102 by a gap 103, and a connector 104 bridging the gap and electrically connecting the chip and the workpiece. Gap 103 may be filled with a polymer material 105. The device in FIG. 1B includes a semiconductor chip 151 spaced from a workpiece 152 by a gap 153, and a connector 154 bridging the gap an electrically connecting the chip and the workpiece. Gap 153 may be filled with a polymer material 155.

Semiconductor chips 101 and 151 are made of a semiconductor material (such as silicon, silicon germanium, or gallium arsenide) and have an active surface (101a, 151a), which is preferably covered by one or more layers of an overcoat (111, 161) such as silicon nitride or silicon oxynitride for mechanical and moisture protection. Overcoat thicknesses range preferably between about 20 and 30 μm, but may be thinner. Windows in the overcoat expose portions of the chip metallization as contact pads (110, 160) at pad locations. In advanced high speed devices, the size of the windows has been reduced well below the conventional 50 to 70 μm squared. The contact pads are preferably made of copper; alternatively, they may include aluminum or an aluminum alloy.

Insulating layers 111 and 161 may more generally be solder masks; when they define the exposed metals 110 and 160 as shown in FIG. 1A, the metal pads are often referred to as solder mask-defined metal pads.

Workpiece 102 and workpiece 152 may be another semiconductor chip, or they may be an insulating substrate integral with conductive lines and vias. In either case, the workpiece has a surface (102a, 152a), which is preferably covered by a protective overcoat (121, 171). The thickness of the overcoat may be between 10 and 30 μm. Windows in the overcoat expose the workpiece contact pads. In the configuration illustrated in FIG. 1A, the contact 120 is referred to as non-soldermask defined metal trace (metal line). Preferably, trace 120 is copper, positioned on top surface 102a. In FIG. 1B, the contact pad 170 is a solder mask-defined metal layer, preferably copper, imbedded in surface 152a. Contact pad 120 has a metallurgical surface configuration amenable to solder attachment; examples are surfaces with thin layers of nickel and palladium. As FIGS. 1A and 1B show, the locations of the workpiece contact pads match the locations of the chip contact pads.

In FIG. 1A, workpiece 102 and chip 101 are spaced by the gap 103. The width of gap 103 varies locally: At the contact pad locations, the gap has the width 103a; between the contact pads, the gap has the width 103b. Width 103a is the distance between chip surface 101a and workpiece surface 102a. Width 103b is smaller than width 103a by the sum of the thicknesses of the overcoat layers on the chip and on the workpiece.

Analogous considerations hold for gap 153 in FIG. 1B.

In FIG. 1A, the main portion at the core of connector 104 is a column-shaped spacer 140, which includes two or more deformed spheres of non-reflow metals bonded together to a height approximately equal to the gap width; the remainder of the connector core and its height is provided by metal trace 120.

As defined herein, the term reflow metals refers to metals or alloys, which melt at temperatures between about 150 and 320° C.; examples are solders made of tin or various tin alloys (containing silver, copper, bismuth, and lead). In contrast, the term non-reflow metals refer to metals or alloys, which melt at temperatures between about 900 and 1200° C.; examples are silver, gold, and copper.

In FIG. 1B, the core of connector 154 is made of a column-shaped spacer 190, which includes a string of deformed spheres (the example of FIG. 1B shows four deformed spheres) of non-reflow metals bonded together. Spacer 190 has a height about equal to the gap width. Preferred non-reflow metal for spacers 140 and 190 is gold or a gold alloy; alternatively, spacers 140 and 190 may be copper or a copper alloy.

As FIGS. 1A and 1B show, the spacers are attached to the chip contact pads (110, 160) substantially normal to the chip surface (101a, 151a) and extend from the chip contact pads to the matching workpiece contact pad (120, 170). The spacers are bonded to the workpiece contact pads by reflow metals (141, 191), preferably tin or tin alloy. The reflow metal covers at least portions of the workpiece contact pads (120, 170) and portions of the spacers (140, 190); in the examples of FIGS. 1A and 1B, the reflow metal covers the spacers completely. The reflow metal, therefore, interconnects the chip (101, 151) and the workpiece (102, 152) electrically.

The gap spacing chip and workpiece may be filled with a polymer material, which surrounds the connectors and preferably includes a precursor based on an epoxy or a polyimide compound. In FIG. 1A the gap-filling polymer is designated 105, surrounding connectors 104, in FIG. 1B the gap-filling polymer is designated 155, surrounding connectors 154. The polymer materials fill the gaps substantially without voids.

Conventional technology uses only single balls to connect the device wafer and the workpiece wafer; the gap between the assembled wafers is thus determined by the size (diameter) of these balls. Consequently, the pitch, center-to-center, between the balls is also limited by the ball diameter and cannot be reduced without simultaneously narrowing the gap. In contrast, according to the invention, the width of the gap is controlled by the height of the spacer and thus the number of the squeezed metal spheres. Consequently, the pitch of the spacers, centerline-to-centerline, is free to shrink without simultaneously shrinking the gap. In this fashion, devices combining narrow pad pitch with wide gaps can be manufactured. For devices with a given pitch of the contact pads, the diameter of the deformed spheres is selected so that the pitch of the contact pads, center to center, is no greater than 150% of the diameter.

Another embodiment of the invention is a method for fabricating a flip-chip and underfilled semiconductor device, which includes a chip and a workpiece spaced by a gap. As stated above, the width of the gap between chip and workpiece may vary around an average value. Since for many devices the gap has to be filled uniformly with polymer material, the invention applies certain laws of fluid dynamics and deformable medium to select the needed spacer height for a preferred polymer precursor with suitable fluid mechanics properties.

For a deformable medium flowing in a gap with different cross sections q in various parts, continuity requires that the amount of deformable medium flowing per unit of time through each cross section be directly proportional to q and to the velocity v in this cross section:
q v=const.
In a gap, a deformable medium flows fastest at the smallest cross section.

The velocity v of the flowing medium of density ρ is correlated to its pressure p after BERNOULLI by
½ρv²+p=const.

The pressure p of a flowing medium is the smaller the greater its velocity is. Consequently, the pressure at the smaller cross sections is smaller than at the larger cross sections.

When the parts of a gap with different cross sections are separated by different lengths l of the gap, one also has to consider the drop of pressure along the gap lengths; the drop, in turn, depends on the characteristics of the flow, laminar versus turbulent.

A deformable medium flowing in a portion of a gap of radius r and length l at a velocity v, averaged over the tube cross section, experiences a pressure drop Δp due to friction. For idealized conditions, such as neglecting the inertia of the flowing medium, HAGEN and POISEUILLE have found for laminar flow
Δp=8 ηl v/r². (η=dynamic viscosity)

The pressure drop of the medium along the gap portion length is directly proportional to the first power of the average velocity and inverse proportional to the second power of the portion radius.

In contrast, for turbulent flow the relationship is
Δp=ρλl v²/r.
(ρ=density, λ=dimensionless number related to REYNOLD's criteria of transition from laminar to turbulent flow).

The pressure drop of the medium along the gap portion length is directly proportional to the second power of the average velocity and inverse proportional to the first power of the portion radius.

Referring to FIG. 1A, for some gap portions the radius r is half the width 103b, and for other gap portions the radius r is half the width 103a. As discussed above, the gap width is determined by the spacer 140.

The method for fabricating a flip-chip and underfilled semiconductor device according to the invention starts by providing a semiconductor wafer with an active and a passive surface; the active surface includes devices with contact pads in pad locations. In the embodiment of FIG. 2, a portion of the semiconductor wafer 201 is shown with active surface 201a, covered by a protective overcoat 202. Windows in overcoat 202 provide access to device metallization 203 as contact pads; the windows thus delineate the contact pad locations. Metallization 203 is preferably made of a copper alloy, which has in the window a surface configuration suitable for wire bonding; the copper may have a surface layer of an aluminum alloy suitable for gold wire bonding, or a stack of a nickel layer followed by a top gold layer (these surface layers are not shown in FIG. 2).

A first free air ball 204, formed on an automated wire bonder, is pressed against the contact pad 203 of device 201 and is somewhat flattened. The diameter 205 may be in the range from about 15 to 120 μm. In this embodiment, the free air ball is made from a bonding wire, which is an alloy rich in gold, yet hardened by mixtures with a small percentage of copper and other metals. In a customary automated wire bonder, the wire (diameter between preferably between about 15 and 90 μm) is strung through a capillary 206. At the tip of the wire, a free air ball or sphere is created using either a flame or a spark technique. The ball has a typical diameter from about 1.2 to 1.6 wire diameters. The capillary is moved towards the metal pad 203 and the ball is pressed against the metal pad. The compression (also called Z- or mash) force is typically between about 17 and 75 g. At time of pressing, the temperature usually ranges from 150 to 270° C. The flame-off tip of the squeezed ball is designated 204a; it is facing outwardly from the device surface 201a.

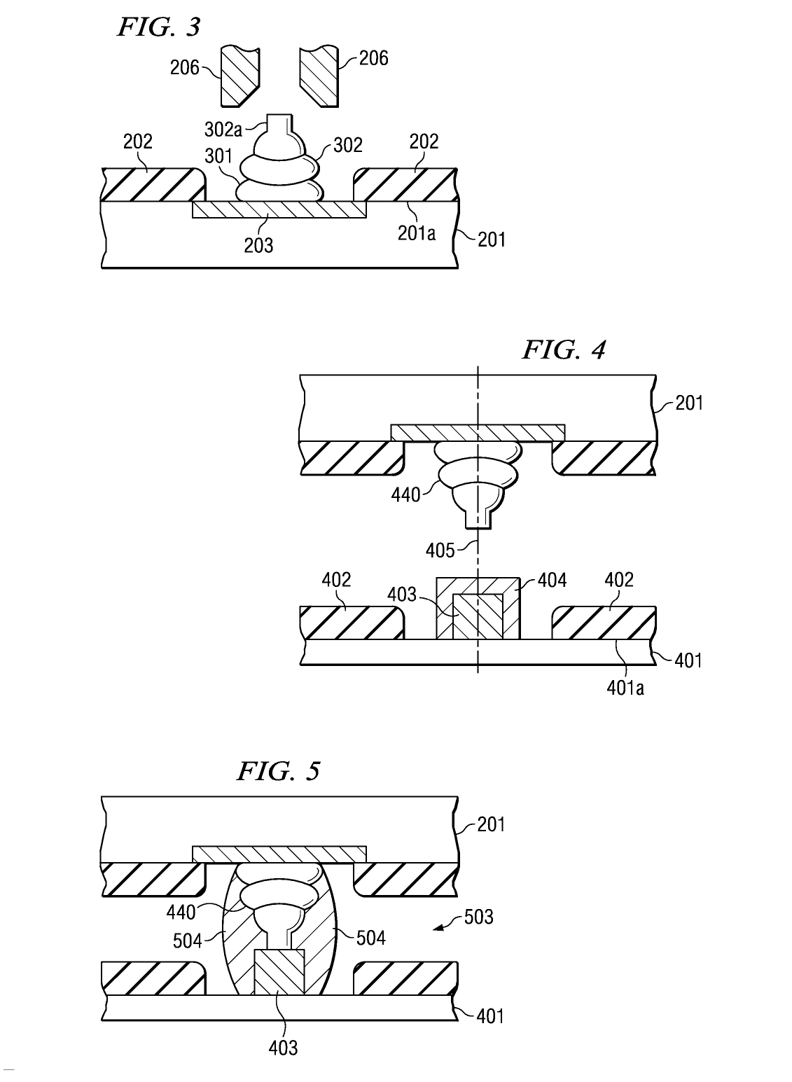

In FIG. 3, a second ball 302 of a size about equal to the first ball is pressed on top of the first ball (now squeezed and designated 301) in a substantially linear sequence, preferably so that the center-to-center line is approximately normal to the equatorial plane of the balls. Slight deviations from the vertical arrangement can be tolerated. The ball-forming and placing may be repeated to create a column-shaped spacer with a height based on the fluid mechanics of the selected underfill material and the required gap width of the device-to-be-created, when the device wafer is flipped on a workpiece wafer.

In FIG. 1B a segmented spacer is shown, which is formed by four squeezed spheres of about equal size, produced and stacked in about linear sequence by automated wire bonding techniques, resulting in a column-shaped spacer. The flame-off tip points outwardly from the attachment surface 151a. The axis of the segmented spacer is approximately normal to the attachment surface.

For many products, the repeated placings produce spacers of about the same height so that the semiconductor wafer and the workpiece wafer are spaced by substantially uniform distance. For some embodiments, however, it is a technical advantage of the invention that pre-determined spacers can be manufactured with more segments than others in order for the spacers to exactly follow unequal surface contours of specific devices.

In the next step of the fabrication method, illustrated in FIG. 4, a workpiece wafer 401 is provided, which has an active surface 401a covered by a protective overcoat 402. Workpiece 401 may be another semiconductor wafer or a sheet-like insulating substrate integral with conductive lines and vias. Windows in overcoat 402 provide access to workpiece metallization 403 as contacts to the workpiece. The embodiment depicted in FIG. 4 shows the workpiece contact metal formed as a stud or bump 403; alternatively, the embodiment in FIG. 1B shows the workpiece contact metal 170 formed as a layer. The locations of the workpiece contact pads match the locations of the chip contact pads.

Next, reflow metal 404 such as tin or tin alloy is applied to the metal of the workpiece contacts. In FIG. 4, the reflow metal is schematically illustrated as a thick layer surrounding metal 403; alternatively, the reflow metal may have a spherical shape or be a paste.

In other embodiments, the reflow metals are applied to the spacers on the device contacts.

The semiconductor wafer 201 is then flipped and placed on the workpiece wafer 401. The wafers are brought into alignment so that the spacers 440 on the device align with the matching workpiece contact pads 403 as depicted in FIG. 4. The alignment is indicated by line 405.

Next, thermal energy is applied to reflow the reflow metals 404 on the workpiece contact pads for bonding the spacers 440 to the workpiece contacts. In addition, the device wafer is lowered onto the workpiece metallization until contact between spacer 440 and metallization 403 is established. This step is illustrated in FIG. 5. In this process, reflow metal 504 may wet portions or all of spacer 440. The semiconductor wafer 201 is thus electrically connected to workpiece wafer 401, yet spaced by a gap 503 according to the height of the spacers 440. The connected wafers are cooled to ambient temperature.

Thereafter, gap 503 is filled with the selected underfill material, preferably an epoxy or polyimide based precursor. The precursor is allowed to polymerize.

For some embodiments, it is advantageous to encapsulate the assembled and underfilled semiconductor and workpiece wafers in a protective material, preferably using a molding compound in a transfer molding technique. Finally, the assembled wafers are singulated, preferably by sawing, into discrete flip-chip and underfilled semiconductor devices.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the embodiments are effective in semiconductor devices and any other device with contact pads, which have to undergo assembly on a substrate or printed circuit board followed by underfilling the gap between device and substrate. As another example, the semiconductor devices may include products based on silicon, silicon germanium, gallium arsenide and other semiconductor materials employed in manufacturing. As yet another example, the concept of the invention is effective for many semiconductor device technology nodes and not restricted to a particular one.

It is therefore intended that the appended claims encompass any such modifications or embodiments.

We claim:

1. A semiconductor device comprising:
a semiconductor chip having a surface that includes first contact pads at pad locations;
a workpiece having a surface including second contact pads matching the first pads;
the workpiece and the chip spaced by a gap with a width;
a column-shaped spacer of a height, including two or more deformed spheres of non-reflow metals bonded together and attached to each first pad, extending from the first pad toward the matching second pad; and
reflow metals covering at least portions of the second pad and the spacer, electrically interconnecting the chip and the workpiece.

2. The device according to claim 1 further having a polymer material of known fluid mechanical properties filling the gap and surrounding the reflow metal and spacer.

3. The device according to claim 2 wherein the spacer height is related to the fluid mechanical properties of the polymer material so that the polymer material fills the gap substantially without voids.

4. The device according to claim 1 wherein the workpiece is an insulating substrate integral with conductive lines and contact pads.

5. The device according to claim 1 wherein the workpiece is a semiconductor chip having contact pads.

6. The device according to claim 1 wherein the sizes of the deformed spheres are about equal.

7. The device according to claim 1 wherein the non-reflow metal includes gold.

8. The device according to claim 1 wherein the non-reflow metal includes copper.

9. The device according to claim 1 wherein the reflow metals include tin and a tin alloy.

10. The device according to claim 1 wherein the polymer material includes a precursor based on an epoxy and polyimide compound.

11. The device according to claim 1 wherein the deformed spheres have a diameter so that the pitch of the first contact pads, center to center, is no greater than 150% of the diameter.

12. A method for fabricating a semiconductor device comprising the steps of:
providing a semiconductor wafer having a surface that includes first contact pads at pad locations;
placing and squeezing a non-reflow metal ball on a first contact pad;
providing a polymer precursor having known fluid mechanics properties as underfill material;
repeating the ball-placing to form a column-shaped spacer having a height related to the fluid mechanics of the selected underfill material;
providing a workpiece wafer having a surface including second contact pads matching the first pads;
applying reflow metal to the contact pads;
placing the workpiece wafer on the device wafer and aligning the second pads to the spacers on the device;
applying thermal energy to reflow the metal on the second pads for bonding the spacers to the workpiece so that the semiconductor wafer and the workpiece wafer are electrically connected, yet spaced by a gap according to the height of the spacers;
filling the gap with the underfill material; and
singulating the assembled wafers into discrete flip-chip and underfilled semiconductor devices.

13. The method according to claim 12, wherein the reflow metal is applied to the first contact pads.

14. The method according to claim 12, wherein the reflow metal is applied to the second contact pads.

15. The method according to claim 12 wherein the workpiece is an insulating substrate integral with conductive lines.

16. The method according to claim 12 wherein the workpiece is a semiconductor wafer.

17. The method according to claim 12 further including the step of encapsulating the assembled and underfilled semiconductor and workpiece wafers in a protective material, before the step of singulation.

18. The method according to claim 12 wherein the non-reflow metal ball is a gold free air ball.

19. The method according to claim 12 wherein the non-reflow metal ball is a copper free air ball.

20. The method according to claim 12 wherein the repeated metal ball placings are produced with a wire bonding process so that the squeezed balls have about equal size and are bonded together to form a column-shaped spacer.
